(19) United States
(12) Patent Application Publication
(10) Pub. No.: US 2003/0010989 A1
(43) Pub. Date: Jan. 16, 2003

(54) Light-emitting diode array

(76) Inventor: Tomihisa Yukimoto, Tokyo (JP)

Correspondence Address: Lee, Mann, Smith, McWilliams,, Sweeney & Ohlson, Suite 410, 209 South LaSalle Street, Chicago, IL, 60604, US

(21) Appl. No.: 10/185,258

(22) Filed: Jun. 28, 2002

(30) Foreign Application Priority Data
Jul. 11, 2001 (JP) 2001-210464

(51) Int. Cl. H01L 33/00

(52) U.S. Cl. 257/88

(57) ABSTRACT

A high-power light-emitting diode array wherein an epitaxial layer prepared by accumulating a plurality of crystal layers is formed on a substrate 1, a plurality of light-emitting diode sections 10, which have been insulated and divided, is contained, and each surface of light-emitting part 12a of the light-emitting diode sections 10 is covered with protective films (11, 14) is characterized in that a total thickness of the protective films covering each surface of light-emitting part 12a of the plurality of light-emitting diode sections 10 is allowed to be 1 μm or thinner.

### BACKGROUND OF THE INVENTION

1. Field of the Invention

The present invention relates to alight-emitting diode array, and particularly to a light-emitting diode array used for a light source in an electrophotographic printer.

2. Prior Art

Laser array light source and light-emitting diode array light source are typically used as a light source for electrophotographic printer. Particularly, since light-emitting diode array does not require a long optical path length unlike laser array, the resulting printer can be downsized, while a material having a large size can be easily printed, on the other hand.

Moreover, downsizing for printer is promoted recently so that a high-precision and high-power light-emitting diode array comes to be demanded.

FIG. 1 is a top view showing a conventional light-emitting diode array, and FIG. 2 is a constitutional view in section taken along the line B-B′ of FIG. 1.

A conventional light-emitting diode array is constituted in such that a plurality of light-emitting diode array sections 10 is disposed in a row on a chip as shown in FIG. 1.

A sectional structure thereof has a double heterostructure as shown in FIG. 2 in such that a p-type GaAs conductive layer 2, a p-type AlGaAs etching stopper layer 3, a p-type AlGaAs cladding layer 4, p-type AlGaAs active layer 5, an n-type AlGaAs cladding layer 6, and an n-type GaAs capping layer 7 are disposed on a semi-insulating GaAs substrate 1 in this order.

Isolation of the light-emitting diode section 10 is performed by mesa-etching components from the n-type GaAs capping layer 7 to the semi-insulating GaAs substrate 1.

A cathode contact electrode 8 for applying a voltage to a light-emitting diode is provided on a mesa top surface of then-type GaAs capping layer 9 and an anode contact electrode 15 is provided on the p-type GaAs conductive layer 2 in such a manner that each metal is evaporated to make each alloy of these electrodes. These electrodes are extended to a cathode bonding pad section 17 and an anode bonding pad section 18 by means of each of Au wirings 16, respectively.

On one hand, light produced in the active layer 5 in the light-emitting diode section 10 cannot pass through the n-type GaAs capping layer 9. Accordingly, the latter layer is removed by means of etching to define a light-emitting part 12 (a surface of light-emitting part 12a) being a part for taking out light. On the surface of light-emitting part 12a, a PSG (Phospho Silicate Glass) insulating film 11 being a protective film for the purpose of insulating the Au wiring 16, a protective PSG film 14, and an SiN film 19 being a denser protective film 19 are disposed.

In the meantime, according to such structure of the light-emitting diode array as described above, light taken out from the surface of light-emitting part 12a is emitted through the PSG insulating film 11, the protective PSG film 14, and the protective SiN film 19.

In this respect, however, there has been such a problem that its luminous efficacy deteriorates due to reflection and refraction of light in these protective films.

### SUMMARY OF THE INVENTION

Accordingly, the present invention has been made to solve the above-described problem involved in the prior art.

An object of the present invention is to provide a high-power light-emitting diode array having a structure for elevating light taking-out efficiency.

In order to achieve the above-described object, a light-emitting diode array according to the present first invention wherein an epitaxial layer prepared by accumulating a plurality of crystal layers is formed on a substrate, a plurality of light-emitting diode sections, which have been insulated and divided, is contained, and each surface of light-emitting part of the light-emitting diode sections is covered with protective films including insulating films is characterized by that a total thickness of the protective films covering each surface of light-emitting part of the plurality of light-emitting diode sections is allowed to be 1 μm or thinner.

In the above-described light-emitting diode array, each of the protective films may be composed of either single insulating film, or plural insulating films. Moreover, a type of the insulating film(s) may be made from any material so far as it can maintain transmittance.

A light-emitting diode array of the present invention is characterized by that the total thickness of the protective films on each surface of the light-emitting part is thinned by etching so as to be 1 μm or less in the above-described light-emitting diode array according to the first invention.

A light-emitting diode array according to the present second invention wherein an epitaxial layer prepared by accumulating a plurality of crystal layers is formed on a substrate, a plurality of light-emitting diode sections, which have been insulated and divided, is contained, and each surface of light-emitting part of the light-emitting diode sections is covered with protective films including a first insulating film and a second insulating film is characterized by that a total thickness of the protective films covering each surface of light-emitting part of the plurality of light-emitting diode sections is allowed to be 1 μm or thinner.

In the above-described second invention, it is sufficient that the total thickness of the protective films including the first insulating film and the second insulating film is 1 μm or less. Accordingly, the following four cases are included in the manner of practice of the second invention.

(1) The first insulating film and the second insulating film exist together wherein a thickness of the second insulating film is thinned.

(2) The second insulating film does not exist, but only the first insulating film exists.

(3) The second insulating film does not exist, and a thickness of the first insulating film is thinned.

(4) The first insulating film and the second insulating film do not exist together.

A light-emitting diode array of the present invention is characterized by that all the thickness of the second insulating film in the protective films on each surface of the light-emitting part is removed by etching, and a part of or the whole thickness of the first insulating film is removed by etching in the above-described light-emitting diode array according to the second invention.

A light-emitting diode array of the present invention is characterized by that the whole thickness of the second insulating film in the protective films on each surface of the light-emitting part is removed by etching, and a part of or the whole thickness of the first insulating film is not removed by etching in the above-described light-emitting diode array according to the second invention.

Two inventions enumerated immediately above are specified by the conditions described in the paragraphs (2), (3) , and (4) in the above four cases, respectively.

A light-emitting diode array according to the present invention is characterized by that the protective films are further covered with another protective film in the above-described first invention.

A light-emitting diode array according to the present invention is characterized by that the protective films are further covered with another protective film in the above-described modified first invention.

A light-emitting diode array according to the present invention is characterized by that the protective films are further covered with another protective film in the above-described former modified second invention.

A light-emitting diode array according to the present invention is characterized by that the protective films are further covered with another protective film in the above-described latter modified second invention.

In the above-described respective modified inventions, when the protective films include a PSG insulating film and a protective PSG film, these protective films are further covered with another protective film such as an SiN film, whereby invasion of moisture and the like is prevented.

Furthermore, the PSG insulating film/protective PSG film/protective SiN film as described above may be formed in the form of a two-layered film such as a protective PSG film/protective SiO₂ film, and a protective SiO₂ film/protective SiN film wherein a film thickness of a two-layered film is to be selected so as to have good light taking-out efficiency based on refractive index in each film and emission wavelength in the active layer.

Hence, the present invention has been made to solve the above-described problem involved in the prior art, and it relates to a light-emitting diode array in which an epitaxial layer prepared by accumulating a plurality of crystal layers is formed on a substrate, and a plurality of light-emitting diode sections, which have been divided by mesa etching grooves, is contained, wherein protective films formed for covering a surface of a light-emitting part are thinned by etching, whereby its luminous efficacy is elevated.

According to the above-described constitution of the light-emitting diode array of the invention, attenuation of light emitted from an active layer resulting from reflection and refraction of light in protective films can be suppressed, so that its optical output can be remarkably elevated.

### BRIEF DESCRIPTION OF THE DRAWINGS

The present invention will be explained in more detail in conjunction with appended drawings, wherein:

FIG. 1 a top view showing a conventional light-emitting diode array;

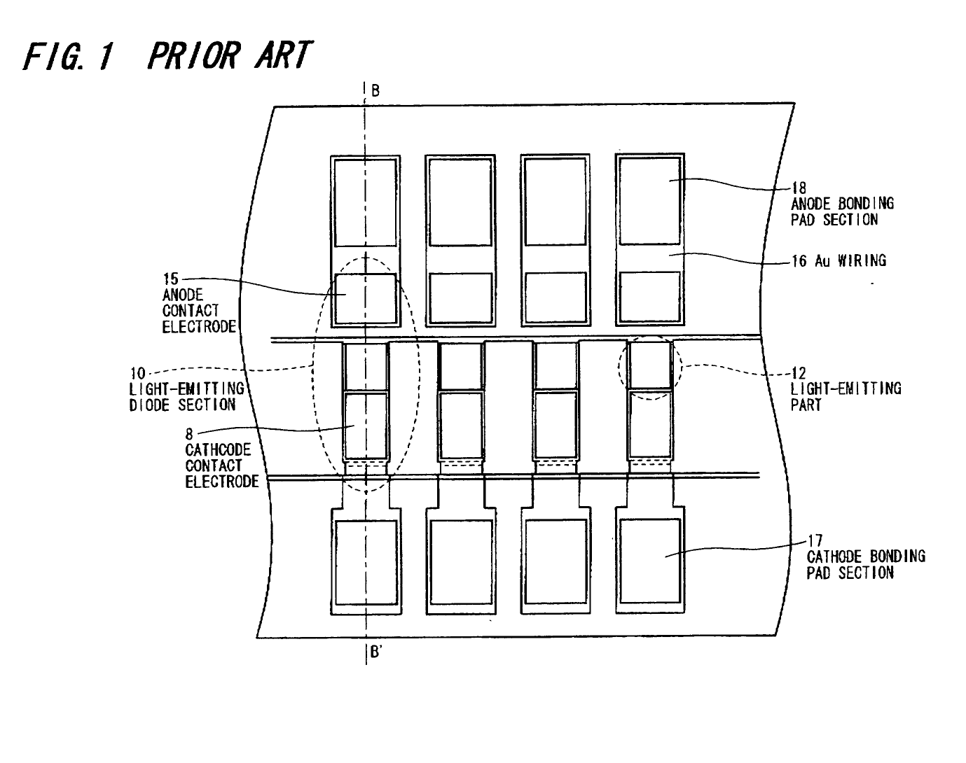

FIG. 2 is a constitutional view, in section taken along the line B-B′ of FIG. 1, showing the conventional light-emitting diode array;

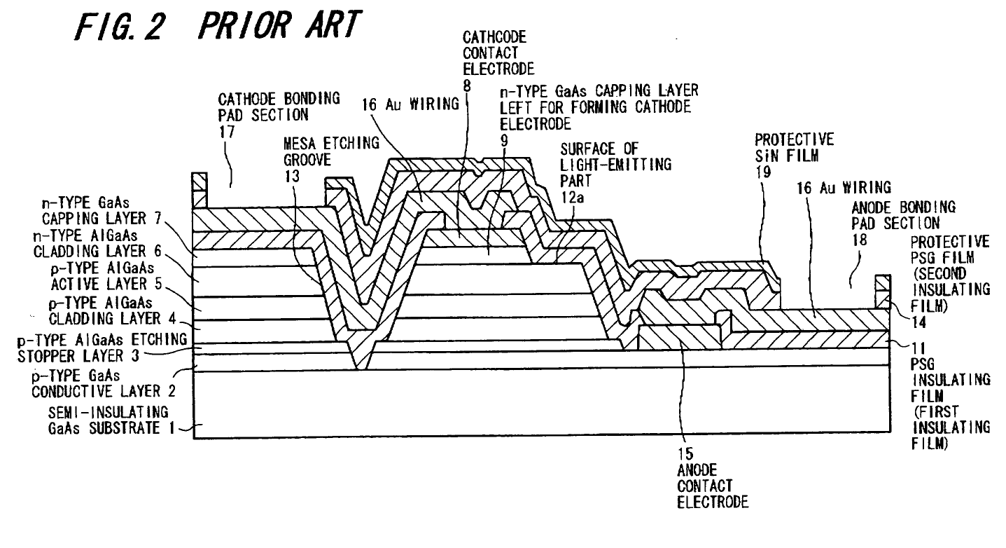

FIG. 3 is a top view showing a light-emitting diode array according to an embodiment of the present invention; and

FIG. 4 is a constitutional view, in section taken along the line A-A′ of FIG. 3, showing the light-emitting diode array according to the embodiment of the present invention.

### DESCRIPTION OF THE PREFERRED EMBODIMENT

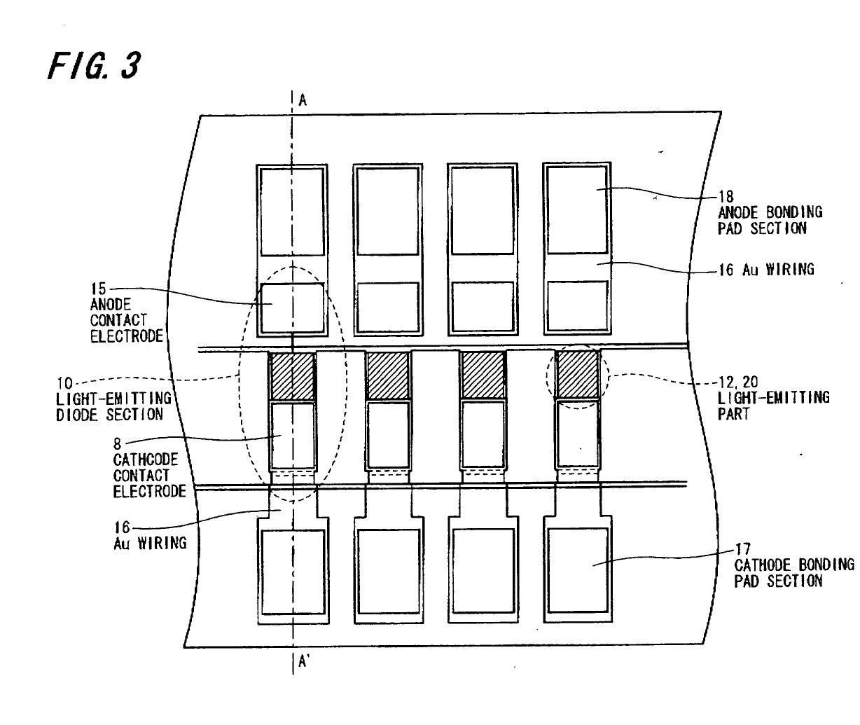

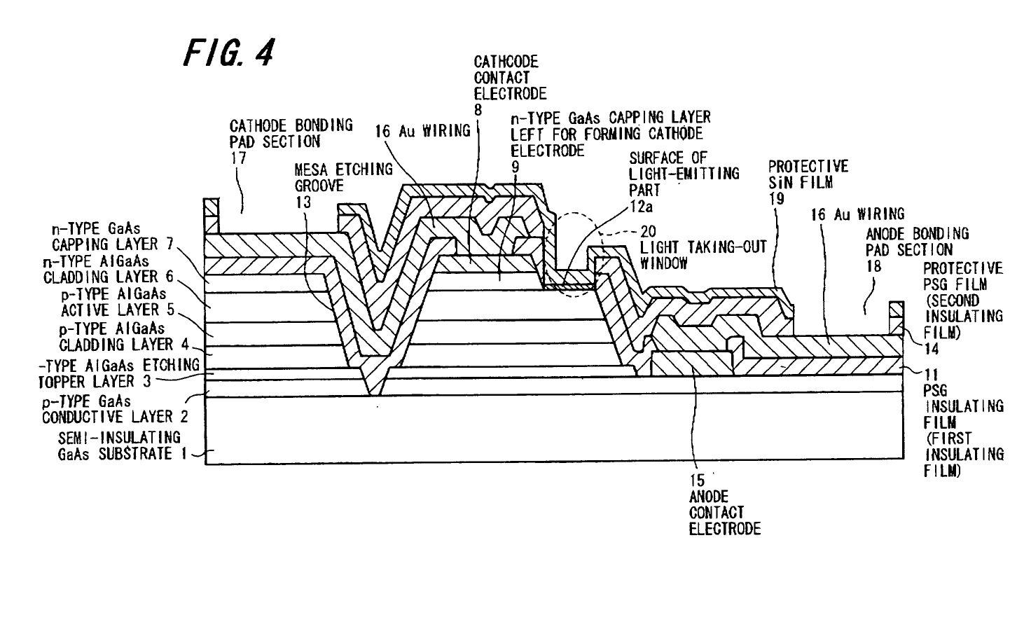

In the following, a preferred embodiment of the present invention will be described in detail in conjunction with the accompanying drawings wherein FIG. 3 is a top view showing a light-emitting diode array according to the present invention, and FIG. 4 is a sectional view showing a structure of the light-emitting diode array taken along the line A-A′ of the FIG. 3.

A light-emitting diode array according to the invention is the one wherein an epitaxial layer prepared by accumulating a plurality of crystal layers is formed on a semi-insulating GaAs substrate 1, a plurality of light-emitting diode sections 10, which have been insulated and divided, is contained, and each surface of light-emitting part 12a of the light-emitting diode sections 10 is covered with protective films of a PSG insulating film 11 (first insulating film)and a protective PSG film 14 (second insulating film) as well as a further protective film of a protective SiN film 19, which is characterized by that a total thickness of the protective films covering each surface of light-emitting part 12a of the plurality of light-emitting diode sections 10 and composed of the PSG insulating film 11 and the protective PSG film 14 is allowed to be 1 μm or less by means of etching, and the resulting protective films are covered with the protective SiN film 19.

As shown in FIGS. 3 and 4, the above-described light-emitting diode array has the same structure as that of a conventional light-emitting diode array except that a light taking-out window 20 is defined on the light-emitting part 12, and the protective films (the PSG insulating film 11 and the protective PSG film 14) are made to be thinned.

In more detail, the light-emitting diode array of the present embodiment is constituted as shown in FIG. 3 in such that each mesa type light-emitting diode section 10 for applying a voltage to emit light is formed on a semi-insulating GaAs substrate 1, and a number of light-emitting parts 12 for taking out light emitted from the light-emitting diode sections 10 to the outside is aligned on mesa top surfaces of the light-emitting diode sections 10 being insulated, respectively, by mesa etching grooves 13.

Furthermore, anode contact electrodes 15 each for applying a voltage to a light-emitting diode section are formed on either side of mesa groove surfaces along lines of these light-emitting parts 12, while each cathode contact electrode 8 is formed on a mesa top surface in each light-emitting part 12 on the other side of mesa top surfaces.

Moreover, each cathode contact electrode 8 is connected electrically with each cathode bonding pad 17 used for connecting the cathode contact electrode 8 with an outside element by means of each Au wiring 16.

FIG. 4 is a constitutional view, in section, showing the light-emitting diode array.

A light-emitting diode section 10 of the light-emitting diode array is constituted as shown in FIG. 4 in such that a p-GaAs conductive layer 2, a p-type AlGaAs etching stopper layer 3, a p-type AlGaAs cladding layer 4, p-type AlGaAs active layer 5, an n-type AlGaAs cladding layer 6, and an n-type GaAs capping layer 7 are laminated on a semi-insulating GaAs substrate 1 in this order, and further the light-emitting diode section 10 is formed into mesa type by means of a mesa etching groove 13.

Moreover, as mentioned above, the cathode contact electrode 8 has been formed on a mesa top surface of the light-emitting diode section 10, while an anode contact electrode 15 is formed on the p-type GaAs conductive layer 2 being a mesa groove surface of the light-emitting diode section 10.

In the following, a process for the production of a light-emitting diode array will be described together with operation of the light-emitting diode array.

One (1) μm of the p-type GaAs conductive layer 2 having 4×10¹⁹ cm⁻³ carrier concentration, 0.5 μm of the p-type AlGaAs layer 3 having 3×10¹⁹ cm⁻³ carrier concentration, 1 μm of the p-type AlGaAs cladding layer 4 having 3×10¹⁸ cm⁻³ carrier concentration, 1 μm of the p-type AlGaAs active layer 5 having 1×10¹⁸ cm⁻³, 3 μm of the n-type AlGaAs cladding layer 6 having 2×10¹⁸ cm⁻³, and 0.5 μm of the n-type GaAs capping layer 7 having 1×10¹⁸ cm⁻³ carrier concentration are sequentially grown on a (100) surface of the semi-insulating GaAs substrate 1 in accordance with MOVPE method.

The n-type GaAs capping layer 7 being the uppermost layer is removed with leaving only a part 9 thereof by means of wet etching.

For the sake of separating electrically the respective diode sections 10, mesa etching grooves 13 are defined by means of wet etching wherein a depth of the etching groove 13 is 7.0 μm so as to expose the GaAs substrate 1.

Furthermore, 0.5 μm of a PSG insulating film 11 (first insulating film) is grown in accordance with CVD method so as to cover the whole surface.

The PSG film 11 on a part of the cathode contact electrode 8 is removed with hydrofluoric acid, while the PSG film on a part of the anode contact electrode 15 is removed by means of dry etching where in a gas such as CHF₃₃/O₂₂ is used. The cathode contact electrode 8 is prepared by evaporating and alloying AuGe/Ni/Au on the n-type GaAs capping layer 9. The anode contact electrode 15 is prepared by evaporating and alloying AuZn/Ni/Au on the p-type GaAs conductive layer 2 which has been exposed on the bottom of a mesa etching groove. These electrodes are drawn out to places of the cathode bonding pad 17 and the anode bonding pad 18 by means of the Au wirings 16, respectively.

Then, the whole surface of these components is covered with 0.5 μm of the PSG film 14 (second insulating film) being a protective film.

In this case, a total thickness of the PSG film is 1 μm, which is obtained by adding 0.5 μm of the PSG insulating film 11 (first insulating film) to 0.5 μm of the PSG film 14 (second insulating film). There is, however, such a problem that light taking-out efficiency is low due to reflection and refraction of light in these protective films in case where there is no modification.

According to the present invention, a part or the whole of the protective films composed of the PSG insulating film 11 and the protective PSG film 14 is removed by means of dry etching wherein a gas system such as CHF₃/O₂ is used to obtain a structure having the total thickness of these protective films is 1 μm or thinner, whereby a light taking-out window 20 is defined.

In the present embodiment, the whole thickness of the protective PSG film 14 being the second insulating film has been removed by etching, and further a part of the whole thickness of the PSG insulating film 11 being the first insulating film has been also removed by etching, whereby a thickness of the PSG insulating film 11 has been reduced to 0.25 μm or thinner.

Furthermore, the whole surface of the resulting integrated components is covered with the SiN film 19 being a denser film for the sake of preventing invasion of moisture and the like. Finally, protective films on the respective bonding pads 17 and 18 are removed to produce a light-emitting diode array in a state where in an electric wiring can be made with respect to the resulting light-emitting diode array.

Since reflection and refraction of light in the protective films can be suppressed to the minimum by the light-emitting diode array thus produced, its external luminous efficacy is elevated, so that 1.5 times higher light output than that of a conventional light-emitting diode array can be obtained.

In the present embodiment, the whole thickness of the protective PSG film 14 being the second insulating film has been removed by etching, and a part of the whole thickness of the PSG insulating film 11 being the first insulating film has been removed by means of etching. However, the present invention is not limited to this embodiment, but it may be modified as enumerated hereinafter.

(i) A part of the thickness of the protective PSG film 14 being the second insulating film may be removed by etching.

(ii) The whole thickness of the protective PSG film 14 being the second insulating film may be removed by etching.

(iii) The whole thickness of the protective PSG film 14 being the second insulating film may be removed by etching, besides the whole thickness of the PSG insulating film 11 being the first insulating film may be removed also.

Although PSG and SiN have been employed as protective films in the present embodiment, the other protective films may be used.

Furthermore, a crystal structure in a light-emitting diode has been prepared by disposing p-type crystals and n-type crystals on the semi-insulating GaAs substrate 1 in such that a p-type crystal is positioned at the undermost plane, and an n-type crystal is followed in this order, so that a p-type crystal is positioned always in a lower plane than that of an n-type crystal in the present embodiment, but the invention may be applied also to another crystal structure prepared by disposing n-type crystals and p-type crystals on the semi-insulating GaAs substrate 1 in such that an n-type crystal is positioned at the undermost plane, and a p-type crystal is followed in this order, so that an n-type crystal is positioned always in a lower plane than that of a p-type crystal. In the latter modification, only a polarity of the resulting diode changes, and the light-emitting diode array thus prepared exhibits also an advantage of an improvement in external luminous efficacy.

Moreover, while a semi-insulating GaAs substrate has been used as a substrate in the present embodiment, even a conductive substrate is also applicable so far as it is modified in such that either a high resisting layer such as undoped GaAs is disposed on the conductive substrate, or a p-n-p or an n-p-n structure is arranged, whereby the conductive substrate can be electrically insulated.

After all, a light-emitting diode array according to the present invention wherein a surface of a light-emitting part of a light-emitting diode section is covered with protective films composed of insulating films is characterized by that the total thickness of the protective films is made thinner than 1 μm. Accordingly, a high-power light-emitting diode array having higher light taking-out efficiency than that of a conventional light-emitting diode array having a structure wherein protective layers having the total thickness of 1 μm or thicker have been formed on a surface of a light-emitting part can be provided by the present invention.

The presently disclosed embodiment is therefore considered in all respects to be illustrative and not restrictive. The scope of the invention is indicated by the appended claims rather than the foregoing description, and all changes that come within the meaning and range of equivalents thereof are intended to be embraced therein.

What is claimed is:

1. A light-emitting diode array wherein an epitaxial layer prepared by accumulating a plurality of crystal layers is formed on a substrate, a plurality of light-emitting diode sections, which have been insulated and divided, is contained, and each surface of light-emitting part of said light-emitting diode sections is covered with protective films including insulating films,wherein:
a total thickness of said protective films covering each surface of light-emitting part of said plurality of light-emitting diode sections is allowed to be 1 μm or thinner.

2. A light-emitting diode array as claimed in claim 1, wherein:
the total thickness of said protective films on each surface of said light-emitting part is thinned by etching so as to be 1 μm or less.

3. A light-emitting diode array wherein an epitaxial layer prepared by accumulating a plurality of crystal layers is formed on a substrate, a plurality of light-emitting diode sections, which have been insulated and divided, is contained, and each surface of light-emitting part of said light-emitting diode sections is covered with protective films including a first insulating film and a second insulating film, wherein:
a total thickness of said protective films covering each surface of light-emitting part of said plurality of light-emitting diode sections is allowed to be 1 μm or thinner.

4. A light-emitting diode array as claimed in claim 3, wherein:
the whole thickness of the second insulating film in said protective films on each surface of said light-emitting part is removed by etching, and a part of or the whole thickness of said first insulating film is removed by etching.

5. A light-emitting diode array as claimed in claim 3, wherein:
the whole thickness of the second insulating film in said protective films on each surface of said light-emitting part is removed by etching, and a part of or the whole thickness of said first insulating film is not removed by etching.

6. A light-emitting diode array as claimed in claim 1, wherein:
said protective films are further covered with another protective film.

7. A light-emitting diode array as claimed in claim 2, wherein:
said protective films are further covered with another protective film.

8. A light-emitting diode array as claimed in claim 3, wherein:
said protective films are further covered with another protective film.

9. A light-emitting diode array as claimed in claim 4, wherein:
said protective films are further covered with another protective film.

10. A light-emitting diode array as claimed in claim 5, wherein:
said protective films are further covered with another protective film.
